(19) United States
(12) Patent Application Publication
(10) Pub. No.: US 2005/0167670 A1
(43) Pub. Date: Aug. 4, 2005

(54) Array substrate with a low wire impedance and method of making the same

(76) Inventors: Toshikazu Fujimoto, Omura-shi (JP); Toshiaki Arai, Yokohama-shi (JP); Masaya Tanaka, Fajisawa-shi (JP)

Correspondence Address: THOMAS, KAYDEN, HORSTEMEYER & RISLEY, LLP, 100 GALLERIA PARKWAY, NW, STE 1750, ATLANTA, GA, 30339-5948, US

(21) Appl. No.: 11/036,892

(22) Filed: Jan. 14, 2005

(30) Foreign Application Priority Data
Jan. 16, 2004 (JP) 2004-008600

(51) Int. Cl. H01L 29/04

(52) U.S. Cl. 257/72

(57) ABSTRACT

For some embodiments of the present disclosure, an array substrate includes a transparent insulating substrate, a plurality of wires positioned on the transparent insulating substrate, a first insulating film positioned on the transparent insulating substrate and in between the wires, and a second insulating film positioned on the wires and on the first insulating film. By virtue of the first insulating film positioned between the wires, the wires are completely covered by the first insulating film and the second insulating film.

### TECHNICAL FIELD

The present disclosure relates to an array substrate adapted for use in a liquid crystal display (LCD).

### BACKGROUND

A typical liquid crystal display (LCD) substantially includes an array substrate, a color filter (CF) substrate positioned above and parallel to the array substrate, and a liquid crystal layer filled therein. The array substrate generally includes a plurality of gate lines arranged alternately and a plurality of signal lines arranged alternately and orthogonal to the gate lines, and insulated from the gate lines.

Recently, large-sized and fine pitch LCDs have become popular. Accordingly, the wires laid in many LCDs become thinner and lengthier, and the pitch between wires becomes narrower. Consequently, wire impedance increases and the capacitance in wire-overlapped regions enlarges. These result in signal delay problems.

As shown in FIG. 14, an edge of a pulse 45 that flows in a wire 46 is rounded due to wire impedance or the capacitance between wires 46. Here, the pulse 45 travels from the left side toward the right side of FIG. 14.

There are many ways to reduce the signal delay in the wire 46. One of them is to reduce the wire impedance. To achieve this goal, the length of the wire 46 is reduced, or the cross-sectional area of the wire 46 is increased. However, since the length of the wire 46 is mostly governed by the display size of the LCD, increasing the cross-sectional area of the wire 46 is a more feasible way.

In order to increase the cross-sectional area of the wire 46, there are two choices. One involves widening the wire 46, and another involves thickening the wire 46. However, thickening the wire 46 is a better solution, since widening the wire 46 would reduce the aperture ratio of the LCD.

Thickening the wire 46, nevertheless, makes it difficult to successively form an insulating film on the wires or between the wires. The reason is detailed in FIG. 15 and FIG. 16. Referring to an array substrate 48 shown in FIG. 15, if a wire 50a, such as a gate line, formed on an insulating substrate 12 is significantly thin, then the differential height D₁ of the insulating film 52 may be significantly small, even when the insulating film 52 is formed by a chemical vapor deposition (CVD) process. The small height D₁, however, ensures that the surface of the insulating film 52 has a smooth surface, making it easier to deposit or coat other thin films thereon. For example, the insulating film 52, when formed by a CVD process, may have a thickness of approximately 3000 angstroms. In addition, the material of the insulating film 52 can be silicon nitride, silicon oxide, or silicon oxynitride, which respectively have relative permittivity (also known as dielectric constant) values of 6 to 7, 4, and 4 to 5.

Next, in an array substrate 54 of FIG. 16(a), a wire 50b is thickened to about 6000 angstroms. Here, the differential height D₂ of the insulating film 52 is far larger than D₁. Accordingly, the surface of the insulating film 52 becomes uneven. In addition, the insulating film 52 that covers the sides of the wire 50b becomes thinner, and thus cannot properly cover the wire 50b. In such a case, the wire 50b is not well insulated, and therefore the yield of LCDs is reduced.

As shown by the array substrate 56 of FIG. 16(b), a coated insulating film 58 made of non-photosensitive materials is also possible. In such a case, the insulating film 58 is formed by performing the following steps. First, the coated insulating film 58 is disposed on the insulating substrate 12. Subsequently, the coated insulating film 58 is spread out by performing a spin coating process. Next, an organic solvent contained in the coated insulating film 58 is evaporated. Note, the insulating film 58 formed by spin coating is not even, and therefore, the reliability of the array substrate 56 is reduced. Further, evaporation of the organic solvent makes the insulating film have an uneven thickness.

Furthermore, the relative permittivity of the coated insulating film 58 is approximately half, having a value of about 3, of the insulating film 52 formed by a CVD process. Therefore, the coated insulating film 58 should be thinner than the insulating film 52 (e.g., a silicon nitride layer). However, it is difficult to make the coated insulating film 58 thin. Also, a bumpy surface 62, as shown on an array substrate 60 in FIG. 16(c), often occurs on the coated insulating film 58 when the film 58 is made thinner. In contrast, if the coated insulating film 58 is thickened, the performance of a thin film transistor (TFT) will be degraded. Therefore, the step of forming the insulating film onto the gate line 50b is crucial in the formation of the TFT.

For example, Japan patent publication No. 06-560504 discloses a method in which the coated insulating film is etched back. However, there still remain many problems in controlling the shape of the slope (taper) on the wire's sides. Thus, a heretofore unaddressed need exists in the industry to address the aforementioned deficiencies and inadequacies.

### SUMMARY

It is therefore one objective, among others, of the present disclosure to provide an array substrate with a reduced signal delay in wires and an adjustable capacitance between the gate and the source of the TFT, and methods of making the same.

According to one embodiment of the present disclosure, an array substrate is provided. The array substrate includes an insulating substrate, a plurality of wires positioned on the insulating substrate, a first insulating film positioned on the insulating substrate and between the wires, and a second insulating film positioned on the wires and on the first insulating film. By virtue of the first insulating film formed between the wires, the wires are completely covered by the first insulating film and the second insulating film.

The first insulating film is formed by forming an insulating material dissolved in a solvent on the insulating substrate, performing a thermal treatment to the insulating material to remove the solvent, and performing an exposure process to the insulating material.

The first insulating film can be further formed between the second insulating film and the wires. The first insulating film can also cover a portion of the upper surface of the wires.

The present disclosure further provides embodiments of a method for fabricating an array substrate. One such embodiment includes the following steps. First, an insulating substrate, which is transparent, is provided, and a plurality of wires are formed on the insulating substrate. Next, a coated insulating film covering the wires is formed on the insulating substrate. Subsequently, the coated insulating film is exposed from the backside of the insulating substrate to form a first insulating film. Thereupon, a portion of the coated insulating film, coated on the upper surface of the wires is removed. Finally, a second insulating film is formed on the wires and the first insulating film.

One embodiment of the method further includes exposing the coated insulating film positioned on any one of the wires from the front side of the insulating substrate prior to, subsequent to, or simultaneously with the step of exposing the coated insulating film from the backside of the insulating substrate.

The step of forming the first insulating film may also include the step of adjusting an amount of exposure from the backside of the insulating substrate to partially expose the coated insulating film positioned on the upper surface of the wires, or further adjusting conditions of a thermal treatment to allow the coated insulating film to partially cover the upper surface of the wires.

The wires of one embodiment of the present disclosure are substantially covered by the first insulating film and the second insulating film despite the larger thickness of the wires. Note, with the thicker wires, the signal delay in wires is reduced. In addition, since the first insulating film can be formed to partially cover the edge of the wires, the performance of a TFT can be well controlled.

These and other advantages of the present disclosure will no doubt become apparent to those of ordinary skill in the art after reading the following detailed description that is illustrated in the various figures and drawings.

### BRIEF DESCRIPTION OF DRAWINGS

FIG. 1 is a cross-sectional diagram of an array substrate of one embodiment of the present disclosure.

FIG. 2 is a cross-sectional diagram of the insulating substrate of FIG. 1 when forming wires.

FIG. 3 is a cross-sectional diagram of the insulating substrate shown in FIG. 2 when forming a coated insulating film.

FIG. 4 is a cross-sectional diagram of the insulating substrate shown in FIG. 3 when performing a backside exposure process.

FIG. 5 is a cross-sectional diagram of the insulating substrate shown in FIG. 4 when removing the coated insulating film, which is not exposed, with a developing solution.

FIG. 6 is a schematic diagram illustrating another embodiment of the present disclosure, in which FIG. 6(a) is a cross-sectional diagram of an array substrate and FIG. 6(b) is a cross-sectional diagram of the array substrate shown in FIG. 6(a) when performing a backside exposure process.

FIG. 7(a) is a cross-sectional diagram of a TFT of one embodiment of the present disclosure.

FIG. 7(b) is a cross-sectional diagram of a conventional TFT.

FIG. 8 is a cross-sectional diagram of an insulating substrate when forming a coated insulating film on a first insulating film according to another embodiment.

FIG. 9 is a cross-sectional diagram of the insulating substrate shown in FIG. 8 after performing a backside exposure process.

FIG. 10 is a cross-sectional diagram of the insulating substrate shown in FIG. 9 when removing the coated insulating film, which is not exposed, with a developing solution.

FIG. 11 is a cross-sectional diagram of the insulating substrate shown in FIG. 10 after performing an etching process.

FIG. 12 is a cross-sectional diagram of the insulating substrate shown in FIG. 11 after removing the coated insulating film.

FIG. 13 is a cross-sectional diagram of the insulating substrate shown in FIG. 12 after forming a second insulating film.

FIG. 14 is a schematic diagram illustrating a conventional signal delay condition.

FIG. 15 is a cross-sectional diagram of a conventional array substrate when wires are thinner.

FIG. 16 is a schematic diagram illustrating thicker wires for reducing the signal delay in wires, in which FIG. 16(a) is a cross-sectional diagram illustrating wires that are not completely covered, FIG. 16(b) is a cross-sectional diagram illustrating a thicker coated insulating film, and FIG. 16(c) is a cross-sectional diagram illustrating an uneven surface of the coated insulating film due to a thinner thickness.

### DETAILED DESCRIPTION

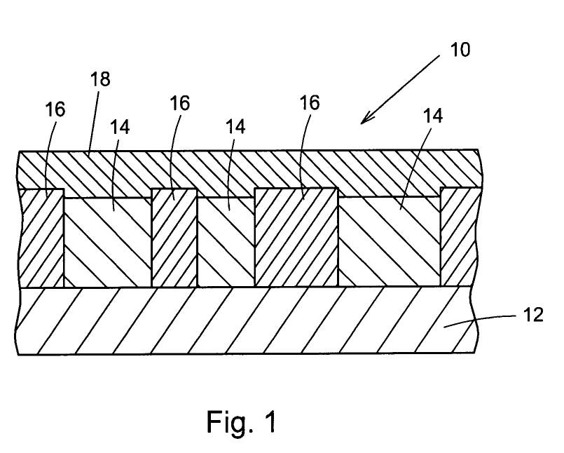

An array substrate of one embodiment of the present disclosure is applicable to a LCD and other suitable products. As shown in FIG. 1, an array substrate 10 includes an insulating substrate 12, a plurality of wires 14 formed on the insulating substrate 12, a first insulating film 16 positioned on the insulating substrate 12 and between the wires 14, and a second insulating film 18 positioned on the wires 14 and the first insulating film 16.

The insulating substrate 12 is a transparent substrate, such as a glass substrate. The wires 14, which are arranged in parallel, are gate lines or wires that make up capacitors. The material of the wires 14 can be molybdenum (Mo), aluminum (Al), chromium (Cr), tantalum (Ta), titanium (Ta), or any suitable conductive material. In this embodiment, the thickness of the wires 14 is approximately 6000 angstroms, which is about twice the thickness of conventional wires. As a result, the wire impedance is reduced, and the signal delay in wires is improved.

The first insulating film 16 is made of a photosensitive insulating material that can be dissolved in a solvent, and treated by a thermal treatment to remove the solvent. Specifically, the first insulating film 16 is a coated insulating film made of a negative photosensitive film. Therefore, after a baking process, the portion of the coated insulating film, which is irradiated by light illumination, will form the first insulating film 16. The negative photosensitive film may be a photoresist resin such as epoxy, polyimide, or polyacrylate, in different embodiments.

The second insulating film 18, which is made of silicon nitride, silicon oxide, or silicon oxynitride, is formed by a CVD process. In the presence of the first insulating film 16, the surface of the second insulating film 18 remains smooth.

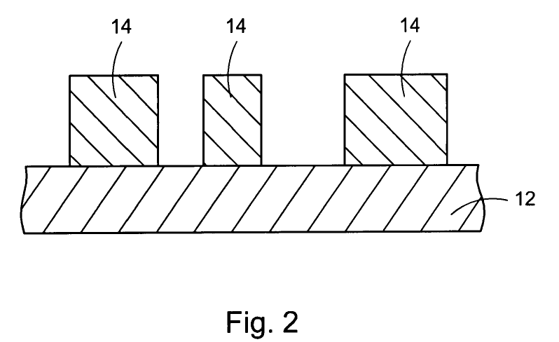

Next, an embodiment of a method of fabricating the array substrate 10 of the present disclosure is illustrated as follows. As shown in FIG. 2, an insulating substrate 12 is provided, and a cleaning process is performed to the insulating substrate 12. Subsequently, a plurality of wires 14 is formed on the insulating substrate 12. In this embodiment, the steps of forming the wires 14 include forming a sputtering layer made of molybdenum (or other conductive material) and patterning the sputtering layer.

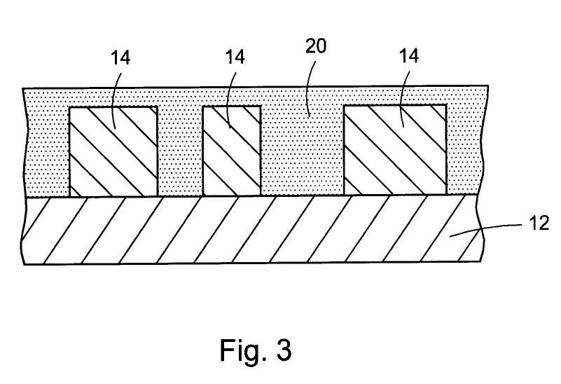

As shown in FIG. 3, a coated insulating film 20 is formed on the insulating substrate 12 and between the wires 14. The steps of forming the coated insulating film 20 include coating a negative photosensitive insulating material on the insulating substrate 12, and thermally treating the insulating substrate 12 to remove the solvent contained in the negative photosensitive insulating material. The coating step may be implemented by spin coating or other coating techniques.

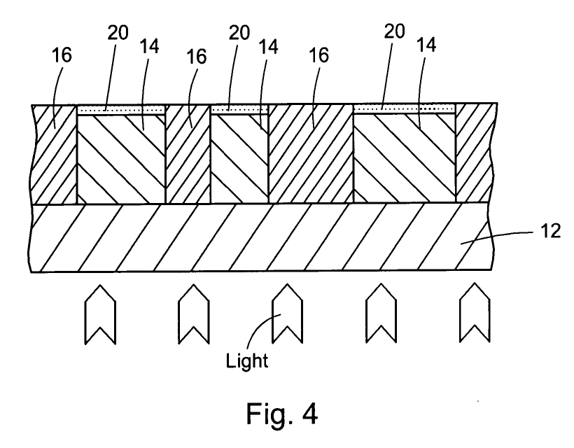

Referring now to FIG. 4, the coated insulating film 20 is exposed from the backside of the insulating substrate 12 using the wires 14 as a shielding mask so as to form a first insulating film 16, in some embodiments. The coated insulating film 20 positioned on the wires 14 is shielded by the wires 14, and therefore is not exposed. Thus, the coated insulating film 20 is exposed without an additional photo mask.

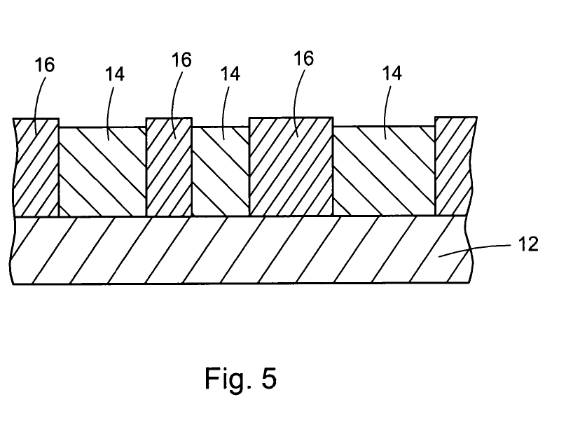

Next, as shown in FIG. 5, since the coated insulating film 20 is negative type, the coated insulating film 20 (that is positioned on the upper surface of the wires 14 and is not exposed) may be easily removed with a developing solution.

As shown in FIG. 1, a second insulating film 18 is then formed on the wires 14 and the first insulating film 16 by, for instance, a CVD process, to form the array substrate 10. The second insulating film 18 may be as thick as a conventional gate insulating film, in some embodiments. In such a case, the characteristics of the TFT will act similar to the TFT formed in a conventional way.

It can be seen that with the first insulating film 16, the surface of the second insulating film 18 remains smooth even though the thickness of the wires 14 is enlarged. Accordingly, the first insulating film 16 and the second insulating film 18 provide an excellent insulating effect. In addition, since the wires 14 are thickened, the signal delay problem of the wires 14 is overcome.

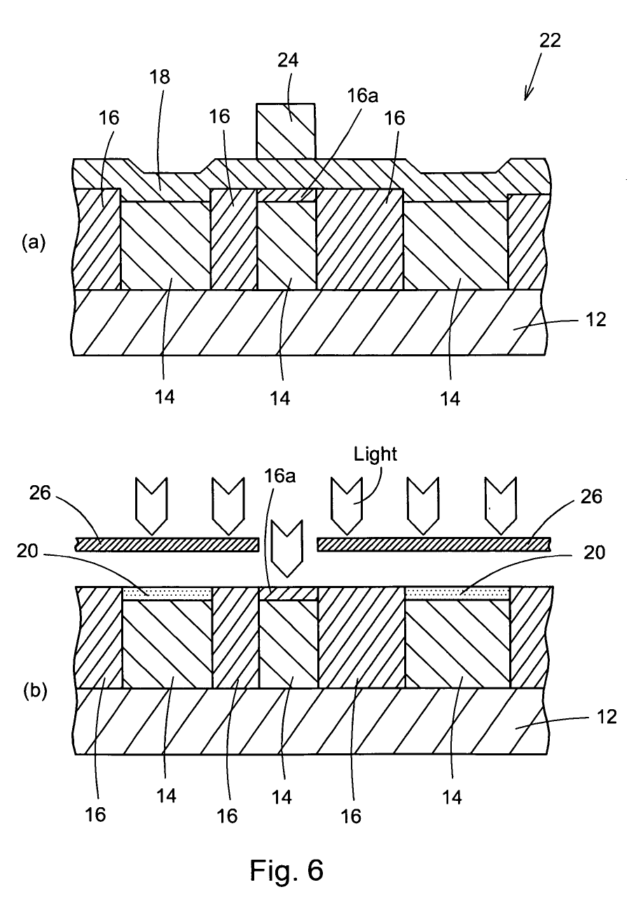

The present disclosure is not limited to the above embodiments. For example, as shown in FIG. 6(a), the insulating film 16 is able to have an extended first insulating film 16a formed between the wires 14 and the second insulating film 18. In addition to the gate lines and the wires that make up the capacitors, an array substrate 22, in some embodiments, further includes a plurality of signal lines 24 positioned above and orthogonal to the wires 14.

While, in conventional systems, the signal delay problem tends to occur in the area in which the signal lines 24 overlap the wires 14, the relative permittivity of the first insulating film 16 is about half that of the second insulating film 18 made of materials, such as silicon nitride, in one embodiment. Thus, the extended first insulating film 16a is able to reduce the capacitance in the overlapped region.

Next, one embodiment of a method of forming the extended first insulating film 16a is shown in FIG. 6(b). First, after the coated insulating film 20 is exposed from the backside of the insulating substrate 12, the coated insulating film 20 is further exposed from the front side of the insulating substrate 12 using a photo mask 26. Consequently, the coated insulating film 20, which has been exposed, cannot typically be removed with a developing solution, and forms the extended first insulating film 16a. Following this step, the second insulating film 18 and the signal lines 24 are consecutively formed thereon. Since the extended first insulating film 16a has a relative permittivity lower than the second insulating film 20, the signal delay problem is avoided due to low capacitances between the wires 14 and the signal lines 24.

The front side exposure process towards the coated insulating film 20 also may be performed prior to, or simultaneously with the backside exposure process. In addition, for the sake of ensuring the pattern of the extended first insulating film 16a, the openings of the photo mask 26 may be enlarged so that the coated insulating film 20 beyond the wires 14 is exposed from the front side of the insulating substrate 12.

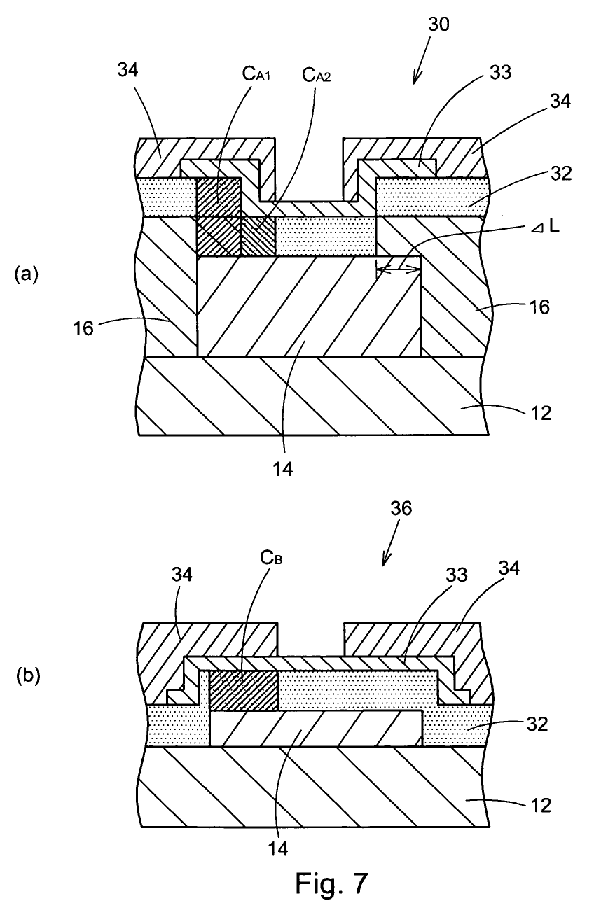

Embodiments of the present disclosure may also be applied to adjust a capacitance of the gate insulating film. Specifically, during the backside exposure process, the coated insulating film positioned above the edge of the gate is also exposed due to a diffraction effect. Therefore, if the duration of the backside exposure process lasts for a longer time, a portion of the coated insulating film positioned above the edge of the gate will also be exposed, forming the first insulating film 16 as shown in FIG. 7(a). In practice, if the exposed time of the coated insulating film is two or three times longer than normal, 1 to 2 micrometers of the coated insulating film will be exposed as ΔL shown in FIG. 7(a). In FIG. 7, reference number 30 denotes the TFT, reference number 32 denotes the gate insulating film, reference number 33 denotes the channel region, and reference number 34 denotes the electrodes.

With the TFT 30 of one embodiment of the present disclosure shown in FIG. 7(a), a capacitance between the gate and the source equals to the sum of capacitances C_{A1}, and C_{A2}. This capacitance can be set by changing the overlapped area between the gate (the wire 14) and the first insulating film 16. In practice, this capacitance can be adjusted by means of altering the amount of exposure in the backside exposure process. Accordingly, the design and manufacture of the array substrate is made more flexible. On the contrary, with the conventional TFT 36 shown in FIG. 7(b), the only way to adjust a capacitance C_{B} is to change the thickness of the gate insulating film 32. Thus, in comparison with the conventional method, one embodiment of a method of the present disclosure is able to reduce the capacitance between the gate and the source, so that the parasitic capacitance is reduced and the aperture ratio is improved.

In addition to performing a backside exposure process, formation of the first insulating film above the edges of the wires 14 can also be implemented by a thermal treatment. After the thermal treatment, the coated insulating film is softened, and will reflow to the positions above the edge of the wires 14. The thermal treatment, in some embodiments, includes two steps. First, after the exposure process, a post-exposure back (PEB) process is performed with a heating plate at 30 degrees Celsius for approximately 90 seconds. Then, the array substrate is heated to 230 degrees Celsius for one hour to harden the coated insulating film. By virtue of these two steps, the coated insulating film reflows and covers the edges of the wires 14.

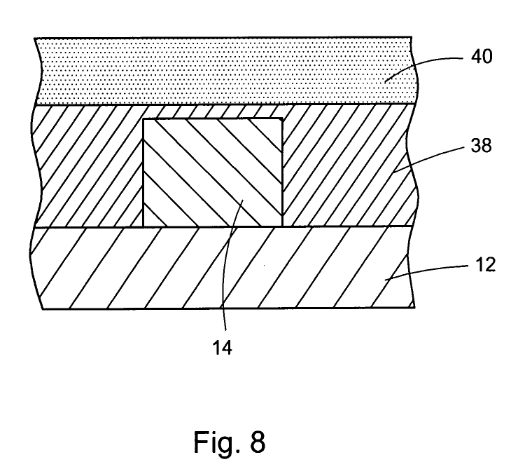

The array substrate 10 shown in FIG. 1 can also be implemented by a method illustrated from FIG. 8 to FIG. 13, for some embodiments. As shown in FIG. 8, an insulating substrate 12 is provided, and a plurality of wires 14 are formed thereon. Subsequently, a first insulating film 38, which is transparent and non-photosensitive, is formed on the insulating substrate 12 and the wires 14. Following this step, a coated insulating film 40, which is a negative photosensitive, is coated on the first insulating film 38.

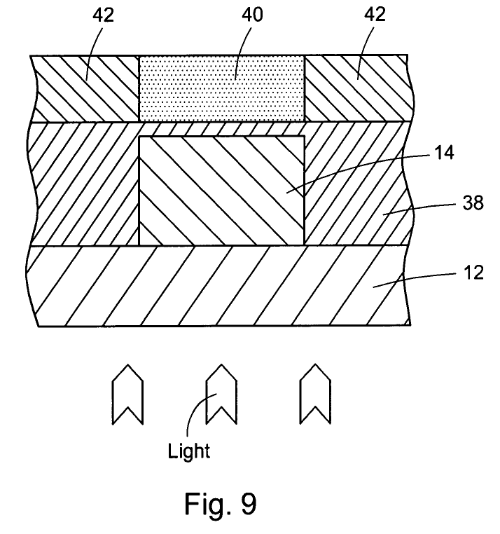

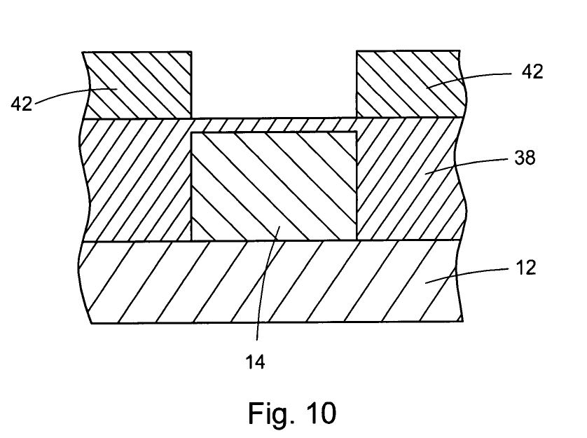

For some embodiments, as shown in FIG. 9, the coated insulating film 40 is exposed from the backside of the insulating substrate 12 using the wires 14 as a shielding mask to form a coated insulating film 42. Then, as shown in FIG. 10, the coated insulating film 40, which is not exposed, is stripped by a developing solution.

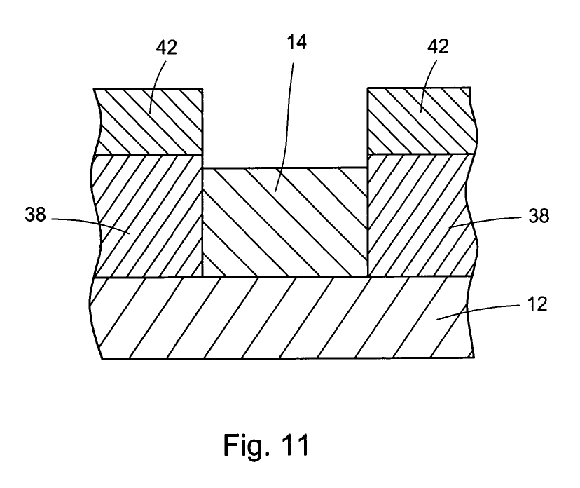

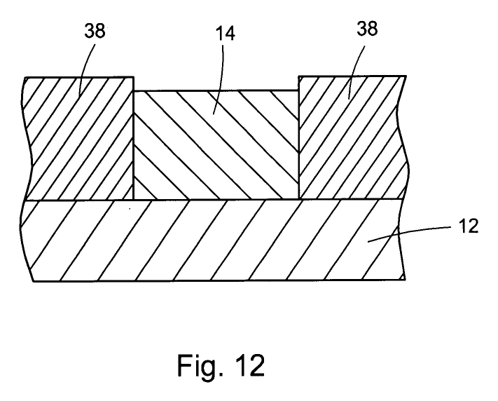

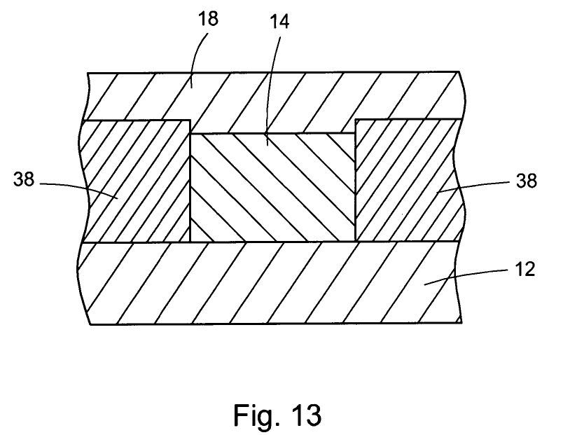

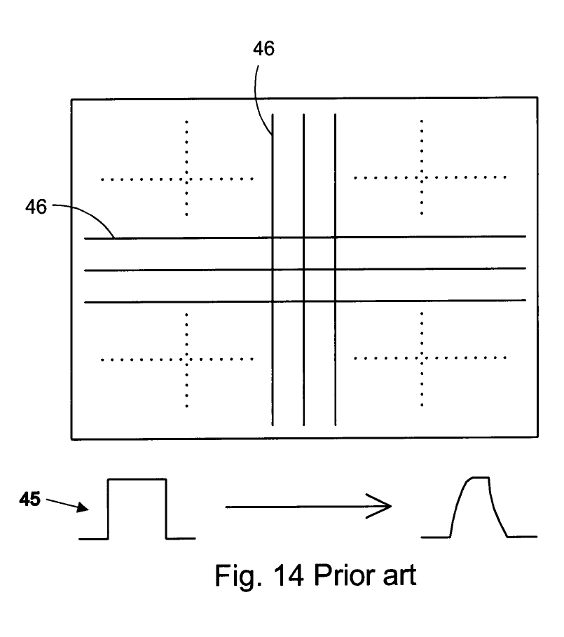

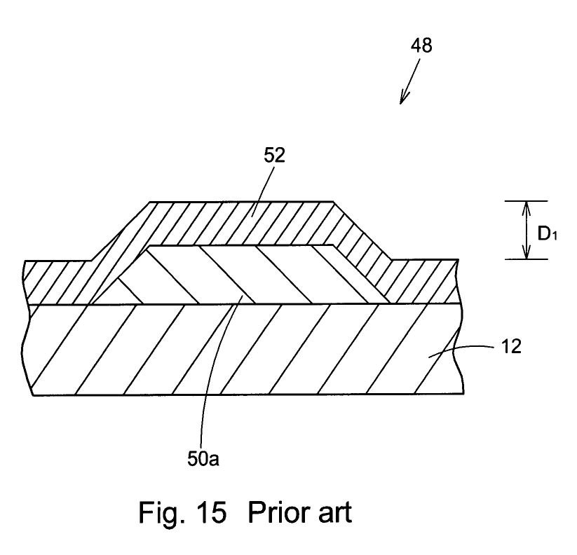

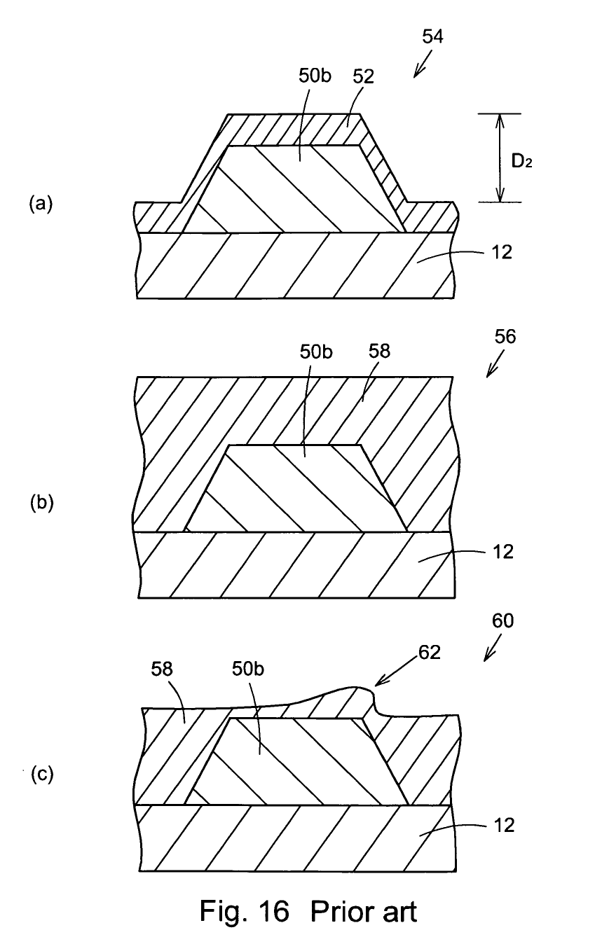

Further, as shown in FIG. 11, an etching process, such as a wet etching process or a dry etching process, is performed using the coated insulating film 42 as a hard mask to etch the first insulating film 38. The coated insulating film 42, in FIG. 11, is removed, as shown in FIG. 12. Thus, a second insulating film 18 is formed on the wires 14 and the first insulating film 38 by a CVD process, for instance, as shown in FIG. 13. Therefore, it can be seen that the array substrate is similar to the array substrate 10 shown in FIG. 1. Consequently, the signal delay problem may also be reduced by virtue of thickening the plurality of wires 14.

Those skilled in the art will readily observe that numerous modifications and alterations of the device and method may be made while retaining the teachings of the present disclosure. Accordingly, the above disclosure should be construed as limited only by the metes and bounds of the appended claims.

1. An array substrate, comprising:
an insulating substrate, the insulating substrate being transparent;
a plurality of wires positioned on the insulating substrate;
a first insulating film positioned on the insulating substrate and between the wires; and
a second insulating film positioned above the wires and the first insulating film.

2. The array substrate of claim 1, wherein the first insulating film is made of a photosensitive insulating material that can be dissolved in a solvent and treated by a thermal treatment.

3. The array substrate of claim 1, wherein the first insulating film is further formed between the second insulating film and the wires.

4. The array substrate of claim 1, wherein the first insulating film covers a portion of an upper surface of the wires.

5. The array substrate of claim 1, wherein each of the plurality of wires is at least approximately 6000 angstroms thick.

6. The array substrate of claim 1, wherein the second insulating film has as smooth surface.

7. The array substrate of claim 1, wherein a relative permittivity of the first insulating film is lower than that of the second insulating film.

8. The array substrate of claim 1, further comprising:
a plurality of signal lines above and orthogonal to the plurality of wires.

9. A method of fabricating an array substrate, comprising:
providing an insulating substrate, the insulating substrate being transparent;
forming a plurality of wires on the insulating substrate;
forming a coated insulating film on the insulating substrate, the coated insulating film further covering the wires;
exposing the coated insulating film from a backside of the insulating substrate to form a first insulating film;
removing a portion of the coated insulating film positioned on an upper surface of the wires; and
forming a second insulating film on the surface of the wires and on the first insulating film.

10. The method of claim 9, further comprising exposing the coated insulating film positioned on any one of the wires from a front side of the insulating substrate prior to the step of exposing the coated insulating film from the backside of the insulating substrate.

11. The method of claim 9, wherein the step of forming the first insulating film comprises:
adjusting an amount of exposure from the backside of the insulating substrate to partially expose the coated insulating film positioned on the upper surface of the wires.

12. The method of claim 9, further comprising exposing the coated insulating film positioned on any one of the wires from a front side of the insulating subsequent to the step of exposing the coated insulating film from the backside of the insulating substrate.

13. The method of claim 9, further comprising exposing the coated insulating film positioned on any one of the wires from a front side of the insulating substrate simultaneously with the step of exposing the coated insulating film from the backside of the insulating substrate.

14. The method of claim 9, wherein the step of forming the first insulating film comprises:
adjusting conditions of a thermal treatment to allow the coated insulating film to partially cover the upper surface of the wires.

15. The method of claim 9, wherein the second insulating film is formed by a chemical vapor deposition process.

16. The method of claim 9, wherein the surface of the second insulating film is smooth.

17. The method of claim 9, further comprising the step of:
forming a plurality of signal lines positioned above and orthogonal to the plurality of wires.

18. The method of claim 9, wherein the first insulating film has a relative permittivity that is lower than that of the second insulating film.

19. The method of claim 9, wherein each of the plurality of wires has a thickness of at least approximately 6000 angstroms.

20. The method of claim 9, wherein the step of forming the first insulating film comprises:
forming an insulating material dissolved in a solvent on the insulating substrate;
performing a thermal treatment to the insulating material to remove the solvent; and
performing an exposure to the insulating material.
